(19) United States
(12) Patent Application Publication
(10) Pub. No.: US 2009/0095222 A1
(43) Pub. Date: Apr. 16, 2009

(54) MULTI-GAS SPIRAL CHANNEL SHOWERHEAD

(76) Inventors: Alexander Tam, Union City, CA (US); Jacob Grayson, Santa Clara, CA (US); Sumedh Acharya, Santa Clara, CA (US)

Correspondence Address: PATTERSON & SHERIDAN, LLP - - APPM/TX, 3040 POST OAK BOULEVARD, SUITE 1500, HOUSTON, TX, 77056, US

(21) Appl. No.: 11/873,141

(22) Filed: Oct. 16, 2007

(51) Int. Cl. C23C 16/00

(52) U.S. Cl. 118/723 R; 118/715

(57) ABSTRACT

A method and apparatus that may be utilized for chemical vapor deposition and/or hydride vapor phase epitaxial (HVPE) deposition are provided. In one embodiment, a metal organic chemical vapor deposition (MOCVD) process is used to deposit a Group III-nitride film on a plurality of substrates. A Group III precursor, such as trimethyl gallium, trimethyl aluminum or trimethyl indium and a nitrogen-containing precursor, such as ammonia, are delivered to a plurality of spiral channels which isolate the precursor gases. The precursor gases are injected into a mixing channel where the gases are mixed before entering a processing volume containing the substrates.

### BACKGROUND OF THE INVENTION

1. Field of the Invention

Embodiments of the present invention generally relate to methods and apparatus for chemical vapor deposition (CVD) on a substrate, and, in particular, to a showerhead design for use in metal organic chemical vapor deposition and/or hydride vapor phase epitaxy (HVPE).

2. Description of the Related Art

Group III-V films are finding greater importance in the development and fabrication of a variety of semiconductor devices, such as short wavelength light emitting diodes (LEDs), laser diodes (LDs), and electronic devices including high power, high frequency, high temperature transistors and integrated circuits. For example, short wavelength (e.g., blue/green to ultraviolet) LEDs are fabricated using the Group III-nitride semiconducting material gallium nitride (GaN). It has been observed that short wavelength LEDs fabricated using GaN can provide significantly greater efficiencies and longer operating lifetimes than short wavelength LEDs fabricated using non-nitride semiconducting materials, such as Group II-VI materials.

One method that has been used for depositing Group III-nitrides, such as GaN, is metal organic chemical vapor deposition (MOCVD). This chemical vapor deposition method is generally performed in a reactor having a temperature controlled environment to assure the stability of a first precursor gas which contains at least one element from Group III, such as gallium (Ga). A second precursor gas, such as ammonia (NH₃), provides the nitrogen needed to form a Group III-nitride. The two precursor gases are injected into a processing zone within the reactor where they mix and move towards a heated substrate in the processing zone. A carrier gas may be used to assist in the transport of the precursor gases towards the substrate. The precursors react at the surface of the heated substrate to form a Group III-nitride layer, such as GaN, on the substrate surface. The quality of the film depends in part upon deposition uniformity which, in turn, depends upon uniform mixing of the precursors across the substrate.

Multiple substrates may be arranged on a substrate carrier and each substrate may have a diameter ranging from 50 mm to 100 mm or larger. The uniform mixing of precursors over larger substrates and/or more substrates and larger deposition areas is desirable in order to increase yield and throughput. These factors are important since they directly affect the cost to produce an electronic device and, thus, a device manufacturer's competitiveness in the market place.

As the demand for LEDs, LDs, transistors, and integrated circuits increases, the efficiency of depositing high quality Group-II nitride films takes on greater importance. Therefore, there is a need for an improved deposition apparatus and process that can provide uniform precursor mixing and consistent film quality over larger substrates and larger deposition areas.

### SUMMARY OF THE INVENTION

The present invention generally provides improved methods and apparatus for depositing Group III-nitride films using MOCVD and/or HVPE.

One embodiment provides a gas delivery apparatus for deposition on a substrate. The apparatus generally includes a first spiral gas channel for a first precursor gas and a second spiral gas channel for a second precursor gas, arranged to be coplanar with the first spiral gas channel.

Another embodiment provides a gas delivery apparatus for deposition on a substrate. The apparatus comprises a first spiral gas channel for a first precursor gas having injection holes through which the first precursor gas is injected into a precursor mixing zone, and a second spiral gas channel for a second precursor gas having injection holes through which the second precursor gas is injected into the precursor mixing zone.

In another embodiment, a gas delivery apparatus for deposition on a substrate is disclosed. The apparatus generally includes a first spiral channel for a first precursor gas, a second spiral channel for a second precursor gas, and a third spiral channel for a heat exchanging medium.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A is a schematic view of a deposition apparatus according to one embodiment of the invention.

FIG. 1B is a detailed cross sectional view of a showerhead assembly shown in FIG. 1A.

FIG. 1C is a detailed cross sectional view of another embodiment of the showerhead assembly shown in FIG. 1B.

FIG. 2A is a detailed cross sectional view of the showerhead assembly shown in FIG. 1B according to one embodiment of the invention.

FIG. 2B is a cross sectional perspective cut-away view of gas channels and heat exchanging channels according to one embodiment of the invention.

FIG. 2C is a cross sectional perspective cut-away view of a showerhead assembly according to one embodiment of the invention.

FIG. 2D is another cross sectional perspective cut-away view of a showerhead assembly according to one embodiment of the invention.

FIG. 2E is a cross sectional perspective double cut-away view of a showerhead assembly according to one embodiment of the invention.

FIG. 2F is a detailed cross sectional view of the showerhead assembly shown in FIG. 2E according to one embodiment of the invention.

FIG. 3 is a cross sectional view of another embodiment of a showerhead assembly according to the present invention.

FIG. 4A is a schematic bottom view of the showerhead assembly shown in FIG. 1B according to one embodiment of the present invention.

FIG. 4B is a schematic bottom view of the showerhead assembly shown in FIG. 1B according to another embodiment of the present invention.

FIG. 5 is a schematic bottom view of additional embodiments of a showerhead assembly according to the present invention.

FIGS. 6A and 6B are schematic bottom views of a showerhead assembly which show different embodiments for gas injection zones.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

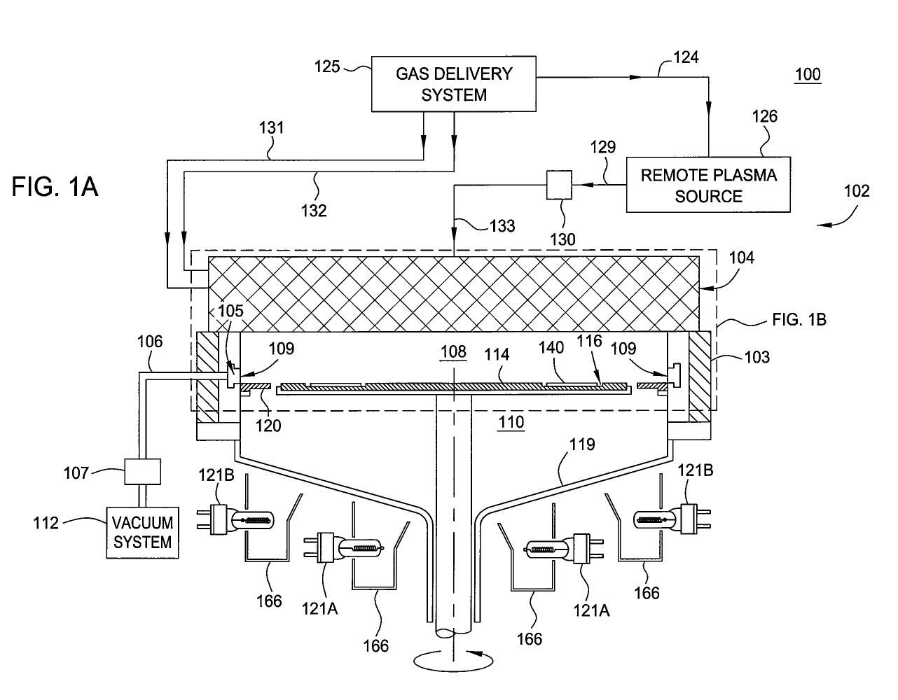

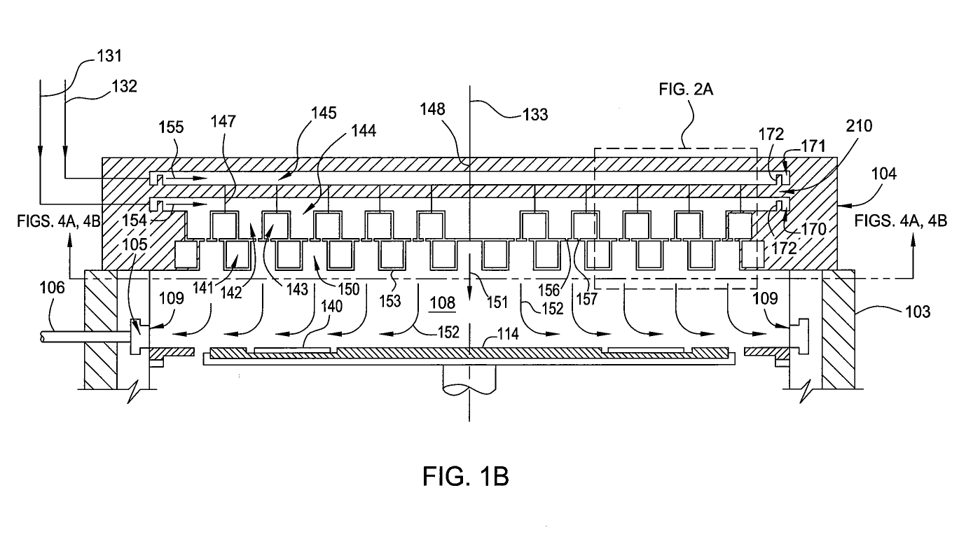

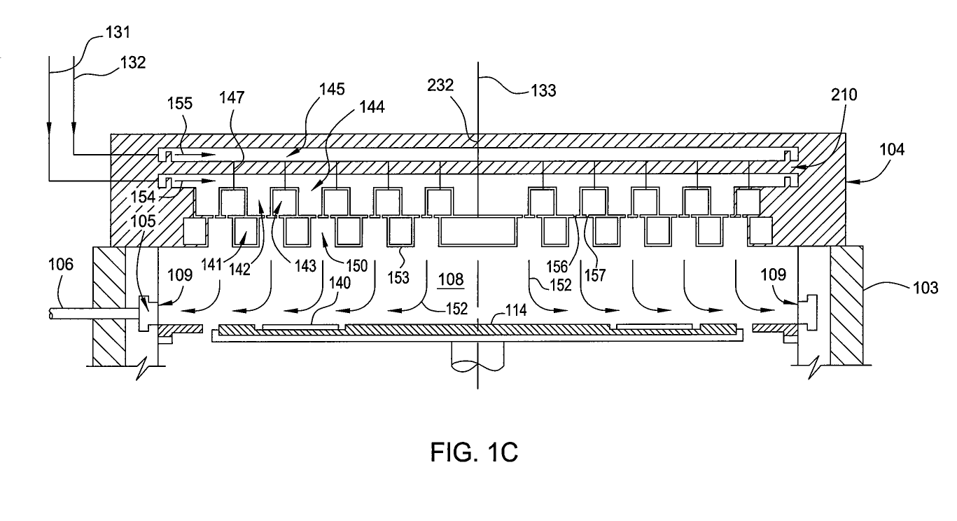

Embodiments of the present invention generally provide a method and apparatus that may be utilized for deposition of Group III-nitride films using MOCVD and/or HVPE. FIG. 1A is a schematic view of a deposition apparatus that may be used to practice the invention according to one embodiment of the invention. Exemplary systems and chambers that may be adapted to practice the present invention are described in U.S. patent application Ser. Nos. 11/404,516, filed on Apr. 14, 2006, and 11/429,022, filed on May 5, 2006, both of which are incorporated by reference in their entireties.

The apparatus 100 shown in FIG. 1A comprises a chamber 102, a gas delivery system 125, a remote plasma source 126, and a vacuum system 112. The chamber 102 includes a chamber body 103 that encloses a processing volume 108. A showerhead assembly 104 is disposed at one end of the processing volume 108, and a substrate carrier 114 is disposed at the other end of the processing volume 108. A lower dome 119 is disposed at one end of a lower volume 110, and the substrate carrier 114 is disposed at the other end of the lower volume 110. The substrate carrier 114 is shown in process position, but may be moved to a lower position where, for example, the substrates 140 may be loaded or unloaded. An exhaust ring 120 may be disposed around the periphery of the substrate carrier 114 to help prevent deposition from occurring in the lower volume 110 and also help direct exhaust gases from the chamber 102 to exhaust ports 109. The lower dome 119 may be made of transparent material, such as high-purity quartz, to allow light to pass through for radiant heating of the substrates 140. The radiant heating may be provided by a plurality of inner lamps 121A and outer lamps 121B disposed below the lower dome 119, and reflectors 166 may be used to help control chamber 102 exposure to the radiant energy provided by inner and outer lamps 121A, 121B. Additional rings of lamps may also be used for finer temperature control of the substrates 140.

The substrate carrier 114 may include one or more recesses 116 within which one or more substrates 140 may be disposed during processing. The substrate carrier 114 may carry six or more substrates 140. In one embodiment, the substrate carrier 114 carries eight substrates 140. It is to be understood that more or less substrates 140 may be carried on the substrate carrier 114. Typical substrates 140 may include sapphire, silicon carbide (SiC), silicon, or gallium nitride (GaN). It is to be understood that other types of substrates 140, such as glass substrates 140, may be processed. Substrate 140 size may range from 50 mm-100 mm in diameter or larger. The substrate carrier 114 size may range from 200 mm-750 mm. The substrate carrier 114 may be formed from a variety of materials, including SiC or SiC-coated graphite. It is to be understood that substrates 140 of other sizes may be processed within the chamber 102 and according to the processes described herein. The showerhead assembly 104, as described herein, may allow for more uniform deposition across a greater number of substrates 140 and/or larger substrates 140 than in traditional MOCVD chambers, thereby increasing throughput and reducing processing cost per substrate 140.

The substrate carrier 114 may rotate about an axis during processing. In one embodiment, the substrate carrier 114 may be rotated at about 2 RPM to about 100 RPM. In another embodiment, the substrate carrier 114 may be rotated at about 30 RPM. Rotating the substrate carrier 114 aids in providing uniform heating of the substrates 140 and uniform exposure of the processing gases to each substrate 140.

The plurality of inner and outer lamps 121A, 121B may be arranged in concentric circles or zones (not shown), and each lamp zone may be separately powered. In one embodiment, one or more temperature sensors, such as pyrometers (not shown), may be disposed within the showerhead assembly 104 to measure substrate 140 and substrate carrier 114 temperatures, and the temperature data may be sent to a controller (not shown) which can adjust power to separate lamp zones to maintain a predetermined temperature profile across the substrate carrier 114. In another embodiment, the power to separate lamp zones may be adjusted to compensate for precursor flow or precursor concentration nonuniformity. For example, if the precursor concentration is lower in a substrate carrier 114 region near an outer lamp zone, the power to the outer lamp zone may be adjusted to help compensate for the precursor depletion in this region.

The inner and outer lamps 121A, 121B may heat the substrates 140 to a temperature of about 400 degrees Celsius to about 1200 degrees Celsius. It is to be understood that the invention is not restricted to the use of arrays of inner and outer lamps 121A, 121B. Any suitable heating source may be utilized to ensure that the proper temperature is adequately applied to the chamber 102 and substrates 140 therein. For example, in another embodiment, the heating source may comprise resistive heating elements (not shown) which are in thermal contact with the substrate carrier 114.

A gas delivery system 125 may include multiple gas sources, or, depending on the process being run, some of the sources may be liquid sources rather than gases, in which case the gas delivery system may include a liquid injection system or other means (e.g., a bubbler) to vaporize the liquid. The vapor may then be mixed with a carrier gas prior to delivery to the chamber 102. Different gases, such as precursor gases, carrier gases, purge gases, cleaning/etching gases or others may be supplied from the gas delivery system 125 to separate supply lines 131, 132, and 133 to the showerhead assembly 104. The supply lines 131, 132, and 133 may include shut-off valves and mass flow controllers or other types of controllers to monitor and regulate or shut off the flow of gas in each line.

A conduit 129 may receive cleaning/etching gases from a remote plasma source 126. The remote plasma source 126 may receive gases from the gas delivery system 125 via supply line 124, and a valve 130 may be disposed between the showerhead assembly 104 and remote plasma source 126. The valve 130 may be opened to allow a cleaning and/or etching gas or plasma to flow into the showerhead assembly 104 via supply line 133 which may be adapted to function as a conduit for a plasma. In another embodiment, apparatus 100 may not include remote plasma source 126 and cleaning/etching gases may be delivered from gas delivery system 125 for non-plasma cleaning and/or etching using alternate supply line configurations to showerhead assembly 104.

The remote plasma source 126 may be a radio frequency or microwave plasma source adapted for chamber 102 cleaning and/or substrate 140 etching. Cleaning and/or etching gas may be supplied to the remote plasma source 126 via supply line 124 to produce plasma species which may be sent via conduit 129 and supply line 133 for dispersion through showerhead assembly 104 into chamber 102. Gases for a cleaning application may include fluorine, chlorine or other reactive elements.

In another embodiment, the gas delivery system 125 and remote plasma source 126 may be suitably adapted so that precursor gases may be supplied to the remote plasma source 126 to produce plasma species which may be sent through showerhead assembly 104 to deposit CVD layers, such as II-V films, for example, on substrates 140.

A purge gas (e.g, nitrogen) may be delivered into the chamber 102 from the showerhead assembly 104 and/or from inlet ports or tubes (not shown) disposed below the substrate carrier 114 and near the bottom of the chamber body 103. The purge gas enters the lower volume 110 of the chamber 102 and flows upwards past the substrate carrier 114 and exhaust ring 120 and into multiple exhaust ports 109 which are disposed around an annular exhaust channel 105. An exhaust conduit 106 fluidly connects the annular exhaust channel 105 to a vacuum system 112 which includes a vacuum pump (not shown). The chamber 102 pressure may be controlled using a valve system 107 which controls the rate at which the exhaust gases are drawn from the annular exhaust channel 105.

FIG. 1B is a detailed cross sectional view of a showerhead assembly shown in FIG. 1A. The showerhead assembly 104 is located near the substrate carrier 114 during substrate 140 processing. In one embodiment, the distance from the showerhead face 153 to the substrate carrier 114 during processing may range from about 4 mm to about 41 mm. In one embodiment, the showerhead face 153 may comprise multiple surfaces of the showerhead assembly 104 which are approximately coplanar and face the substrates 140 during processing.

During substrate 140 processing, according to one embodiment of the invention, process gas 152 flows from the showerhead assembly 104 towards the substrate 140 surface. The process gas 152 may comprise one or more precursor gases as well as carrier gases and dopant gases which may be mixed with the precursor gases. The draw of the annular exhaust channel 105 may affect gas flow so that the process gas 152 flows substantially tangential to the substrates 140 and may be uniformly distributed radially across the substate 140 deposition surfaces in a laminar flow. The processing volume 108 may be maintained at a pressure of about 760 Torr down to about 80 Torr.

Reaction of process gas 152 precursors at or near the substrate 140 surface may deposit various metal nitride layers upon the substrate 140, including GaN, aluminum nitride (AIN), and indium nitride (InN). Multiple metals may also be utilized for the deposition of other compound films such as AIGaN and/or InGaN. Additionally, dopants, such as silicon (Si) or magnesium (Mg), may be added to the films. The films may be doped by adding small amounts of dopant gases during the deposition process. For silicon doping, silane (SiH₄) or disilane (Si₂H₆) gases may be used, for example, and a dopant gas may include Bis(cyclopentadienyl)magnesium (Cp₂Mg or (C₅H₅)₂Mg) for magnesium doping.

In one embodiment, the showerhead assembly 104 comprises first and second annular manifolds 170 and 171, a first plenum 144, a second plenum 145, gas conduits 147, a first gas channel 142, a second gas channel 143, heat exchanging channel 141, mixing channel 150, and a central conduit 148. In one embodiment, the gas conduits 147 may comprise quartz or other materials such as 316L stainless steel, Inconel®, Hastelloy®, electroless nickel plated aluminum, pure nickel, and other metals and alloys resistant to chemical attack.

The first and second annular manifolds 170 and 171 encircle the first and second plenums 144, 145 which are separated by a mid-plate 210. The first and second gas channels 142, 143 each comprise a continuous spiral channel which “spirals out” from a central to a peripheral location of the showerhead assembly 104. The first and second gas channels 142, 143 are adjacent to each other and approximately coplanar and form interleaved spirals. A plurality of first gas injection holes 156 and second gas injection holes 157 are disposed at the bottom of and along the length of each first and second gas channel 142, 143. Disposed beneath first and second gas channels 142, 143 are heat exchanging channel 141 and mixing channel 150 which each comprise a spiral channel. The heat exchanging channel 141 and mixing channel 150 alternate along a radial line of showerhead assembly 104. The heat exchanging channel 141 may be partitioned at various locations along the spiral channel length to form more than one flow loop for heat exchanging fluid. While spiral channels have been disclosed, other arrangements, such as concentric channels, may also be used for the first and second gas channels 142, 143, and heat exchanging channel 141 and mixing channel 150.

The showerhead assembly 104 receives gases via supply lines 131, 132, and 133. In one embodiment, each supply line 131, 132 comprises a plurality of lines which are coupled to and in fluid communication with the showerhead assembly 104. A first precursor gas 154 and a second precursor gas 155 flow through supply lines 131 and 132 into first and second annular manifolds 170, 171 which are in fluid communication with first and second plenums 144 and 145. A non-reactive gas 151, such as an inert gas which may include hydrogen (H₂), nitrogen (N₂), helium (He), argon (Ar) or other gases and combinations thereof, may flow through supply line 133 coupled to a central conduit 148 which is located at or near the center of the showerhead assembly 104. The central conduit 148 may function as a central inert gas diffuser which flows a non-reactive gas 151 into a central region of the processing volume 108 to help prevent gas recirculation in the central region. In another embodiment, the central conduit 148 may carry a precursor gas.

In yet another embodiment, a cleaning and/or etching gas or plasma is delivered through the central conduit 148 into the chamber 102. The central conduit 148 is adapted to disperse the cleaning and/or etching gas or plasma inside chamber 102 to provide more effective cleaning. In other embodiments, the apparatus 100 is adapted to deliver cleaning and/or etching gas or plasma into chamber 102 through other routes, such as the first and second gas injection holes 156, 157. In one embodiment, a fluorine or chlorine based plasma is used for etching or cleaning. In other embodiments, halogen gases, such as Cl₂, Br, and I₂, or halides, such as HCl, HBr, and HI, are used for non-plasma etching.

In another embodiment, the central conduit 148 may function as a metrology port, and a metrology tool (not shown) is coupled to the central conduit 148. The metrology tool is used to measure various film properties, such as thickness, roughness, composition, or other properties. In another embodiment, the central conduit 148 is adapted to function as a port for a temperature sensor, such as a pyrometer or thermocouple.

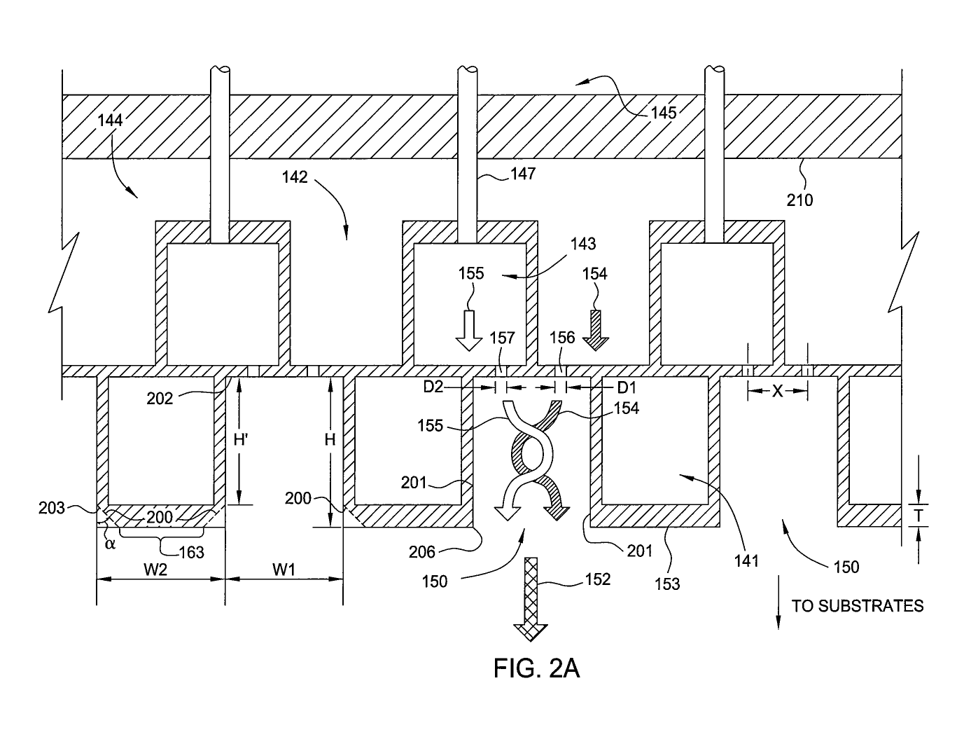

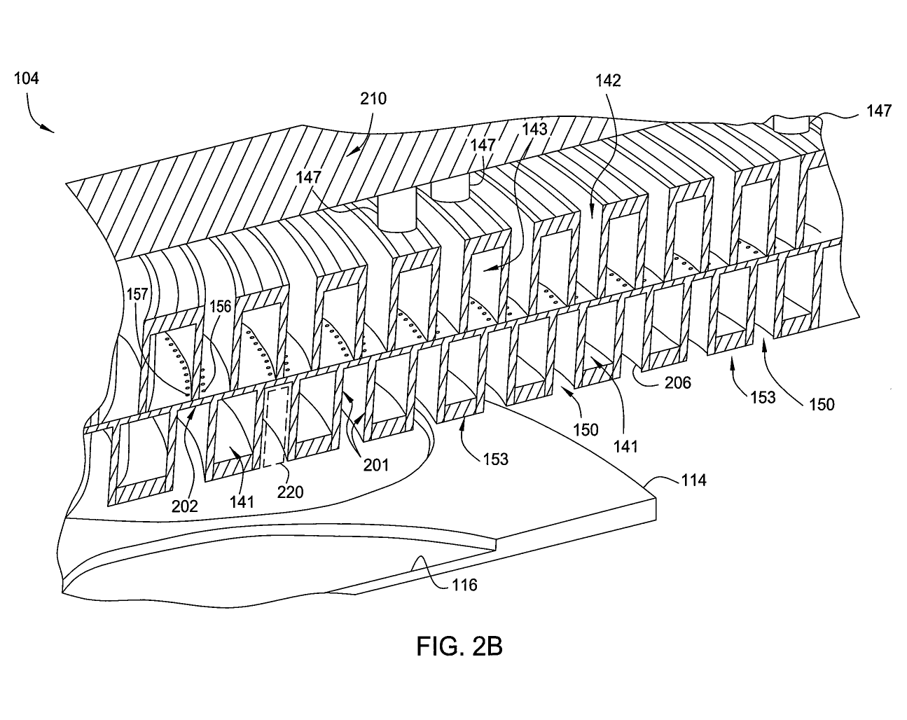

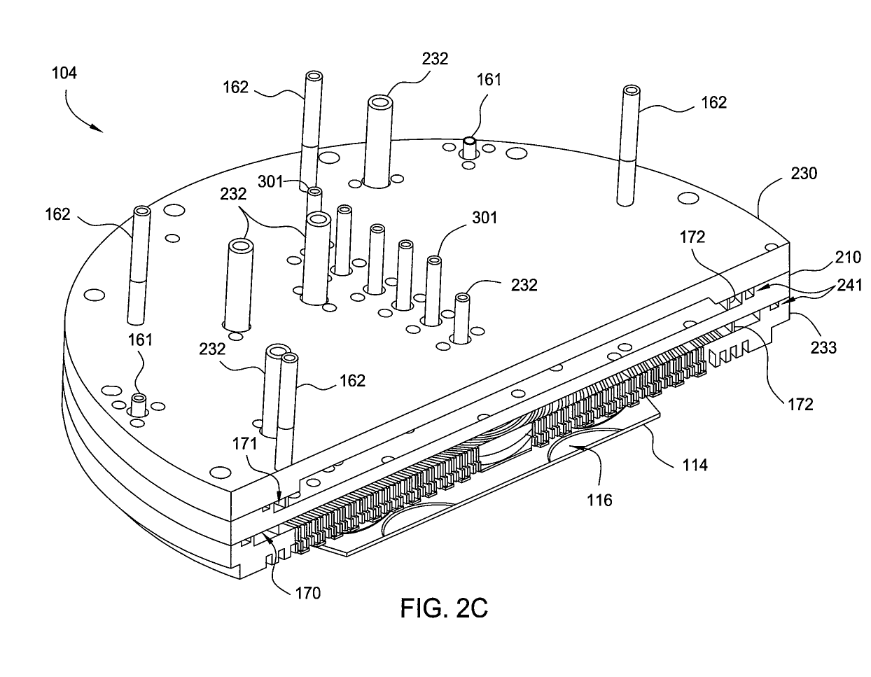

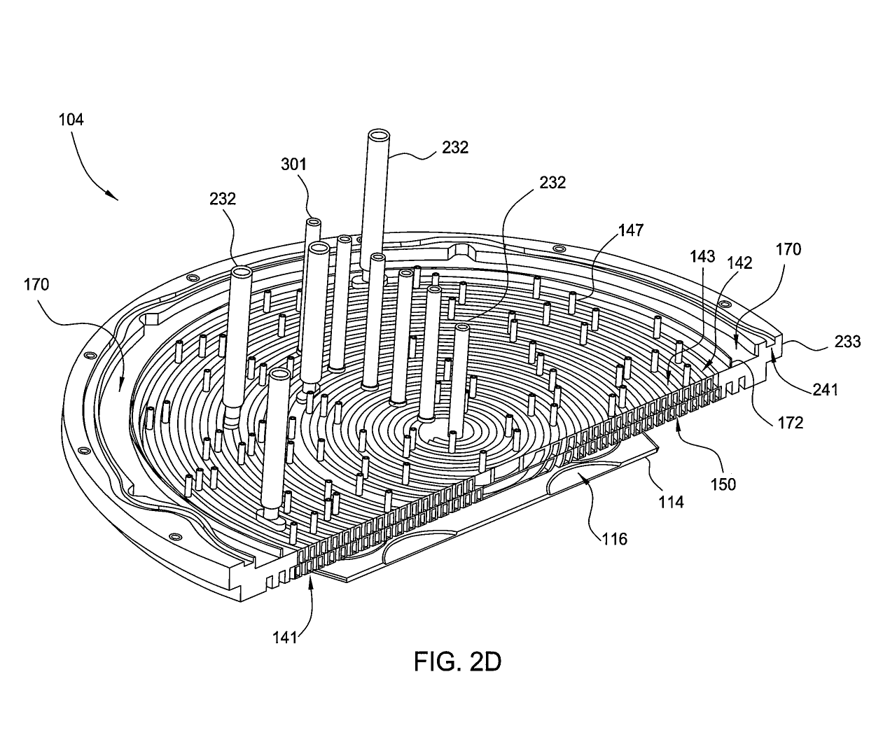

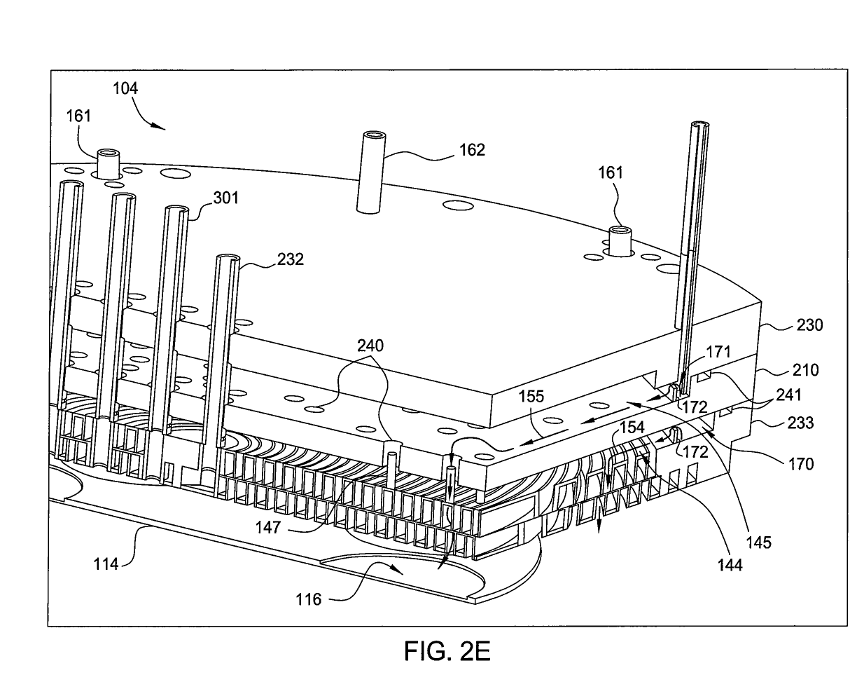

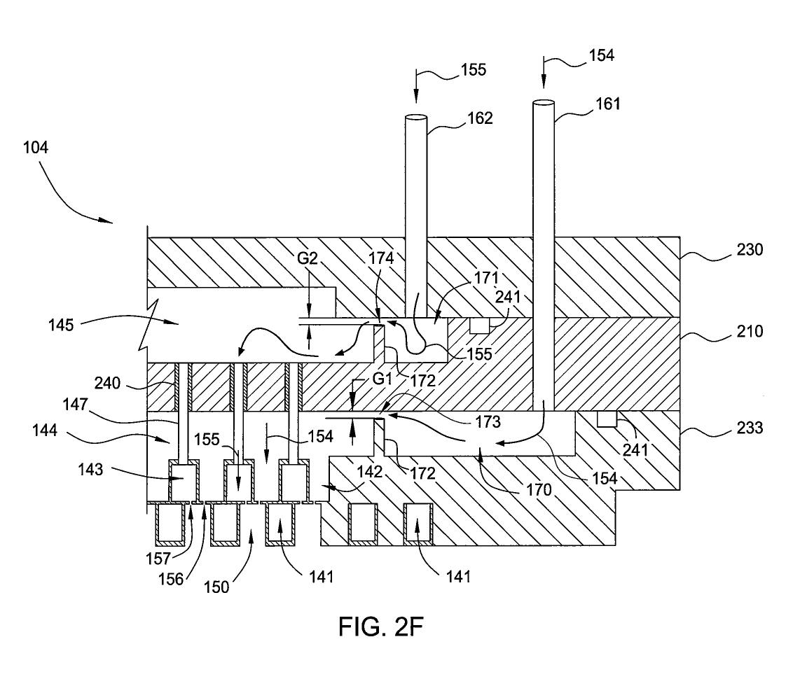

The first and second precursor gases 154, 155 flow from first and second annular manifolds 170, 171 into first and second plenums 144, 145. The first plenum 144 is in direct fluid communication with first gas channel 142, and gas conduits 147 provide fluid communication between second plenum 145 and second gas channel 143. The second gas channel 143 is enclosed to prevent fluid communication with first gas channel 142 and thereby prevent mixing of precursor gases prior to gas injection into mixing channel 150. Restricting walls 172 disposed at the inner diameters of the first and second annular manifolds 170, 171 may have first and second gaps 173, 174 (see FIG. 2F) to provide more uniform gas distribution in the azimuthal direction as gas flows into the first and second plenums 144, 145.

The first and second precursor gases 154, 155 flow from first and second gas channels 142, 143 into first and second gas injection holes 156, 157 and then into a mixing channel 150 where the first and second precursor gases 154, 155 mix to form process gas 152 which then flows into processing volume 108. In one embodiment, a carrier gas, which may comprise nitrogen gas (N₂) or hydrogen gas (H₂) or an inert gas, is mixed with the first and second precursor gases 154, 155 prior to delivery to the showerhead assembly 104.

In one embodiment, the first precursor gas 154 which is delivered to first plenum 144 may comprise a Group III precursor, and second precursor gas 155 which is delivered to second plenum 145 may comprise a Group V precursor. In another embodiment, the precursor delivery may be switched so that the Group III precursor is routed to plenum 145 and the Group V precursor is routed to plenum 144. The choice of first or second plenum 144, 145 for a given precursor may be determined in part by the distance of the plenum from the heat exchanging channels 141 and the desired temperature ranges which may be maintained for each plenum and the precursor therein.

The Group III precursor may be a metal organic (MO) precursor such as trimethyl gallium (“TMG”), trimethyl aluminum (“TMAI”), and/or trimethyl indium (“TMI”), but other suitable MO precursors may also be used. The Group V precursor may be a nitrogen precursor, such as ammonia (NH₃). In one embodiment, a single MO precursor, such as TMG, may be delivered to either plenum 144 or 145. In another embodiment, two or more MO precursors, such as TMG and TMI, may be mixed and delivered to either plenum 144 or 145.

Disposed beneath the first and second gas channels 142, 143 and adjacent to mixing channel 150 is heat exchanging channel 141 through which a heat exchanging fluid flows to help regulate the temperature of the showerhead assembly 104. Suitable heat exchanging fluids include water, water-based ethylene glycol mixtures, a perfluoropolyether (e.g., Galden® fluid), oil-based thermal transfer fluids, or similar fluids. The heat exchanging fluid may be circulated through a heat exchanger (not shown) to raise or lower the temperature of the heat exchanging fluid as required to maintain the temperature of the showerhead assembly 104 within a desired temperature range. In one embodiment, the heat exchanging fluid is maintained within a temperature range of about 20 degrees Celsius to about 120 degrees Celsius. In another embodiment, the heat exchanging fluid may be maintained within a temperature range of about 100 degrees Celsius to about 350 degrees Celsius. In yet another embodiment, the heat exchanging fluid may be maintained at a temperature of greater than 350 degrees Celsius. The heat exchanging fluid may also be heated above its boiling point so that the showerhead assembly 104 may be maintained at higher temperatures using readily available heat exchanging fluids. Also, the heat exchanging fluid may be a liquid metal, such as gallium or gallium alloy.

The flow rate of the heat exchanging fluid may also be adjusted to help control the temperature of the showerhead assembly 104. Additionally, the wall thicknesses of the heat exchanging channels 141 may be designed to facilitate temperature regulation of various showerhead surfaces. For example, the wall thickness T (see FIG. 2A) of the showerhead face 153 may be made thinner to increase the rate of thermal transfer through the wall and thereby increase the cooling or heating rate of the showerhead face 153.

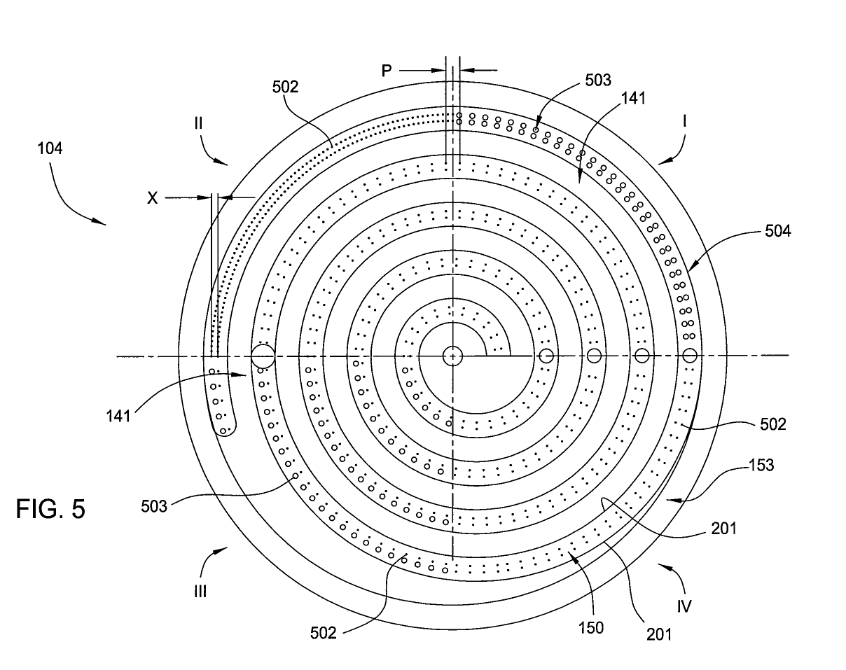

Control of temperature for various showerhead assembly 104 features, such as mixing channels 150 and showerhead face 153, is desirable to reduce or eliminate formation of condensates on the showerhead assembly 104 as well as reduce gas phase particle formation and prevent the production of undesirable precursor reactant products which may adversely affect the composition of the film deposited on the substrates 140. In one embodiment, one or more thermocouples or other temperature sensors are disposed in proximity to showerhead face 153 to measure the showerhead temperature. The one or more thermocouples or other temperature sensors are disposed near central conduit 148 and/or outer perimeter 504 (see FIG. 5) of showerhead assembly 104. In another embodiment, one or more thermocouples or other temperature sensors are disposed in proximity to heat exchanging channel 141 inlets and outlets. In other embodiments, the temperature sensor is located in proximity to other showerhead assembly 104 features.

The temperature data measured by the one or more thermocouples or other temperature sensors may be sent to a controller (not shown) which may adjust the heat exchanging fluid temperature and flow rate to maintain the showerhead temperature within a predetermined range. In one embodiment, the showerhead temperature may be maintained at about 50 degrees Celsius to about 350 degrees Celsius. In another embodiment, the showerhead temperature may be maintained at a temperature of greater than 350 degrees Celsius.

FIG. 1C is a detailed cross sectional view of another embodiment of the showerhead assembly shown in FIG. 1B. Central conduit 148 may be replaced by a heat exchanging fluid conduit 232 disposed at or near the center of showerhead assembly 104 and supply line 133 may be adapted to flow a heat exchanging fluid. The heat exchanging fluid conduit 232 may function as a supply or return line for heat exchanging channels 141.

FIG. 2A is a detailed cross sectional view of the showerhead assembly shown in FIG. 1B according to one embodiment of the invention. The first and second precursor gases 154, 155 flow from first and second gas channels 142, 143 into first and second gas injection holes 156, 157 and then into mixing channel 150. The first gas injection hole 156 has diameter D1, and the second gas injection hole 157 has diameter D2. In one embodiment, the diameters D1 and D2 are equal, and may range from about 0.25 mm to about 1.5 mm. In another embodiment, the diameters D1 and D2 of first and second gas injection holes 156, 157 may not be equal. For example, the second gas injection hole 157 which may supply a nitrogen precursor, such as ammonia (NH3), may have a diameter D2 which is greater than diameter D1 for first gas injection hole 156 which may supply a metal organic precursor. The hole diameters D1 and D2 may be selected to facilitate laminar gas flow, avoid gas recirculation, and help provide the desired gas flow rates for first and second precursor gases 154, 155 through first and second gas injection holes 156, 157. In one embodiment, the gas flow rates through each first and second gas injection hole 156, 157 may be approximately equal. The first and second gas injection holes 156, 157 have a separation distance X which may be selected to facilitate gas mixing and minimize gas recirculation.

The first and second precursor gases 154, 155 mix within the mixing channel 150 to form process gas 152. The mixing channel 150 allows the first and second precursor gases 154, 155 to mix partially or fully before entering the processing volume 108, where additional precursor mixing may occur as the process gas 152 flows towards the substrates 140. This “pre-mixing” of the first and second precursor gases 154, 155 within the mixing channel 150 may provide more complete and uniform mixing of the precursors before the process gas 152 reaches the substrates 140, resulting in higher deposition rates and improved film qualities.

Vertical walls 201 of the mixing channel 150 may be formed by the outer or exterior walls of heat exchanging channel 141 which is adjacent to the mixing channel 150. In one embodiment, the mixing channel 150 comprises exterior walls formed by vertical walls 201 which are substantially parallel to each other. The height H of the mixing channel 150 may be measured from channel surface 202 to a corner 206 where the mixing channel 150 terminates. In one embodiment, the height H of the mixing channel 150 may range from about 5 mm to about 15 mm. In another embodiment, height H of the mixing channel 150 may exceed 15 mm. In one embodiment, the width W1 of the mixing channel 150 may range from about 1 mm to about 5 mm, and the width W2 of the heat exchanging channel 141 may be from about 2 mm to about 8 mm.

In another embodiment, corner 206 may be replaced by a chamfer, bevel, radius, or other geometrical feature to produce diverging walls 200 (indicated by dashed lines) at one end of a mixing channel 150 having a height H′ measured from channel surface 202 to corner 203 where the mixing channel 150 terminates. The distance between the diverging walls 200 may increase in the direction of the substrates 140 so that the surface area of the showerhead face 163 is reduced and the gas flow path widens as the process gas 152 flows downstream. The reduction in surface area of the showerhead face 163 may help reduce gas condensation, and the diverging walls 200 may help reduce gas recirculation as the process gas 152 flows past the heat exchanging channels 141. A diverging angle α may be selected to increase or decrease the surface area of the showerhead face 153 and help reduce gas recirculation. In one embodiment, the angle α is zero degrees. In another embodiment, the angle α is 45 degrees. In another embodiment, a heat exchanging channel 141 may have a corner 206 on one side of the channel and a diverging wall 200 on the opposite side of the channel.

FIG. 2B is a cross sectional perspective cut-away view of gas channels and heat exchanging channels according to one embodiment of the invention. The first and second gas channels 142, 143 are spiral channels which extend over and across the substrate carrier 114 having recesses 116 for substrates 140. At the bottom of each first and second gas channel 142, 143 are a plurality of first and second gas injection holes 156, 157 which provide fluid communication between first and second gas channels 142, 143 and mixing channel 150. In one embodiment, the first and second gas injection holes 156, 157 may comprise drilled holes which are disposed near corners of the first and second gas channels 142, 143. In one embodiment, the spiral mixing channel 150 has a substantially rectangular cross section 220. Heat exchanging channel 141 is disposed at each side of the mixing channel 150 to form vertical walls 201. Heat exchanging fluid may flow through the heat exchanging channel 141 to help control the temperature of mixing channel 150, showerhead face 153, and other showerhead assembly 104 features.

The showerhead assembly 104 may be designed so that it may be disassembled to facilitate cleaning and part replacement. Materials which may be compatible with the processing environment and may be used for the showerhead assembly 104 include 316L stainless steel, Inconel®, Hastelloye®, electroless nickel plated aluminum, pure nickel, molybdenum, tantalum and other metals and alloys resistant to degradation and deformation from high temperatures, thermal stress, and reaction from chemical precursors. To help reduce assembly complexity and ensure isolation of the different gases and liquids which flow through the assembly, electroforming may also be used to fabricate various parts of the showerhead assembly 104. Such electroformed parts may reduce the number of parts and seals required to isolate the different gases and liquids within the assembly. Additionally, electroforming may also help reduce fabrication costs for those parts which have complex geometries.

FIG. 2C is a cross sectional perspective cut-away view of a showerhead assembly 104 according to one embodiment of the invention. The showerhead assembly 104 may comprise a bottom plate 233, a mid-plate 210, and a top plate 230 which are coupled together and the bottom plate 233 may further comprise first and second gas channels 142, 143, mixing channel 150, and heat exchanging channel 141. One or more o-rings (not shown) and o-ring grooves 241 may be disposed near the peripheries of the plates to provide fluid seals and ensure that the first and second plenums 144, 145 are not in fluid communication. One or more sensor tubes 301 may be disposed along or near a radius of the showerhead assembly 104 to provide measurement access for sensors (e.g., temperature sensors) and/or metrology tools to processing volume 108. Two or more heat exchanging fluid conduits 232 may be disposed at various locations in the showerhead assembly 104 to provide heat exchanging fluid inlets and outlets for one or more flow loops for heat exchanging channel 141. In one embodiment, three flow loops may be used for heat exchanging channel 141.

One or more first gas conduits 161 may be in fluid communication with first annular manifold 170 and each first gas conduit 161 may be coupled to and in fluid communication with supply line 131. In one embodiment, six first gas conduits 161 are spaced apart by about 60 degrees near the periphery of top plate 230. Additionally, one or more second gas conduits 162 may be in fluid communication with second annular manifold 171 and each second gas conduit 162 may be coupled to and in fluid communication with supply line 132. In one embodiment, six second gas conduits 162 are spaced apart by about 60 degrees near the periphery of top plate 230.

FIG. 2D is another cross sectional perspective cut-away view of a showerhead assembly according to one embodiment of the invention. Bottom plate 233 comprises spiral channels which extend across and over substrate carrier 114. First annular manifold 170 and restricting wall 172 are disposed near the periphery of the bottom plate 233. Heat exchanging fluid conduits 232 are connected to and in fluid communication with heat exchanging channel 141.

First gas channel 142 is open to first plenum 144 and a plurality of gas conduits 147 may be connected to and in fluid communication with second gas channel 143 and second plenum 145. The first and second gas channel 142, 143 are each a single, continuous channel which “spirals out” from a central to a peripheral location of the bottom plate 233 and thus each spiral channel may have a considerable length. The use of multiple gas conduits 147 may provide more uniform gas distribution along the length of the second gas channel 143. In one embodiment, 50 to 150 gas conduits 147 may be disposed along the spiral of second gas channel 143 such that the gas conduits 147 are spaced apart by about 51 mm to about 76 mm.

FIG. 2E is a cross sectional perspective double cut-away view of a showerhead assembly according to one embodiment of the invention. A second precursor gas 155 may be delivered to second annular manifold 171 and second plenum 145 via second gas conduit 162. The second precursor gas 155 may then flow into one of a plurality of holes 240 disposed in mid-plate 210 and into gas conduit 147 and second gas channel 143 to mixing channel 150. Each of the gas conduits 147 may be disposed within a hole 240 and a suitable sealing device (not shown) may be disposed between the outside diameter of each gas conduit 147 and inside diameter of each hole 240 to form a fluid seal so that the first and second plenums 144, 145 are not in fluid communication. In one embodiment, the second precursor gas 155 may comprise a nitrogen precursor, such as ammonia.

A first precursor gas 154 may be delivered to first annular manifold 170 and first plenum 144 via first gas conduit 161. The first precursor gas 154 may then flow into the open first gas channel 142 at some location along the spiral channel and into a mixing channel 150. In one embodiment, the first precursor gas 154 may comprise a metal organic precursor, such as TMG.

FIG. 2F is a detailed cross sectional view of the showerhead assembly shown in FIG. 2E according to one embodiment of the invention. First and second precursor gases 154, 155 flow into first and second annular manifolds 170, 171 and then flow through first and second gaps 173, 174 disposed at the tops of restricting walls 172. The first and second gaps 173, 174 may be sufficiently narrow to allow the first and second annular manifolds 170, 171 to fill and acquire a more uniform gas distribution in the azimuthal direction as precursor gases flow into first and second plenums 144, 145. Additionally, the first and second gaps 173, 174 have first and second gap sizes G1 and G2 which may be sized to control the gas flow rates into the plenums and promote laminar gas flow. In one embodiment, the first and second gap sizes G1 and G2 are equal and may range from about 0.5 mm to about 1.5 mm. In another embodiment, the first and second gap sizes G1 and G2 may be different.

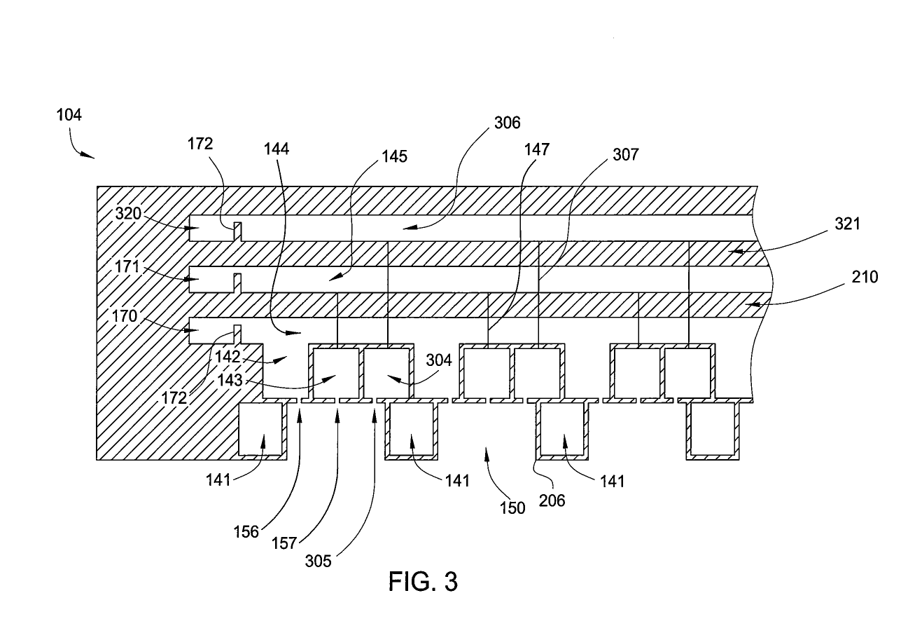

FIG. 3 is a cross sectional view of another embodiment of a showerhead assembly according to the present invention. The apparatus 100 may be adapted to provide additional gas sources and gas supply lines to enable the additional embodiments of the showerhead assembly 104 described herein. FIG. 3 depicts a showerhead assembly 104 which has a third annular manifold 320, a third plenum 306, a second mid-plate 321, and third, enclosed gas channel 304 which is connected to and in fluid communication with conduit 307 so that another gas may be delivered to the mixing channel 150. The gas may be an additional precursor gas or inert gas (such as N₂, He, Ar, for example). The gas may be injected into the mixing channel 150 via third gas injection holes 305. In one embodiment, the first, second and third gas injection holes 156, 157, 305 may all have the same diameter D1. In other embodiments, the first, second, and third gas injection holes 156, 157, 305 may have different diameters. Different embodiments for the gas injection hole diameter D1 have been previously described herein.

Additionally, the gases may be delivered to any one of the first, second and third plenums 144, 145, 306 to form a plurality of possible radial gas injection sequences. For example, the first gas injection hole 156 may inject an MO precursor, the second gas injection hole 157 may inject a nitrogen precursor, such as NH₃, and the third gas injection hole 305 may inject a third precursor gas for a gas injection sequence of MO—NH₃-(third precursor)-repeat where “repeat” indicates that the gas injection sequence is repeated across a radius of the showerhead assembly 104. In another embodiment, the gases may be delivered to the first, second and third plenums 144, 145, 306 to create the gas injection sequence NH₃-MO-(third precursor)-repeat. The addition of a third gas channel 304 forms a three channel sequence 142-143-304-repeat. It is to be understood that the gases are injected simultaneously and the term “gas injection sequence” refers to a spatial and not a temporal sequence. In other embodiments, the showerhead assembly 104 may comprise any number of plenums and gas channels to deliver a plurality of gases in any desired gas injection sequence to the chamber 102.

In another embodiment, the showerhead assembly 104 may have no mixing channel 150 and the heat exchanging channel 141 may be disposed between one or more gas channels to form a substantially flat surface for the showerhead face 153 which comprises a plurality of first, second, and third gas injection holes 156, 157, and 305. In yet another embodiment, the showerhead assembly 104 may have no heat exchanging channel 141. Additionally, an inert gas or gases may be delivered to gas channels to create “curtains” of inert gas, such as N₂, He, Ar or combinations thereof, between precursor gases to help keep the precursor gases separated before reaching the substrates 140. In one embodiment, four gas channels may be used to form a gas injection sequence MO-(inert gas)-NH₃-(inert gas)-repeat.

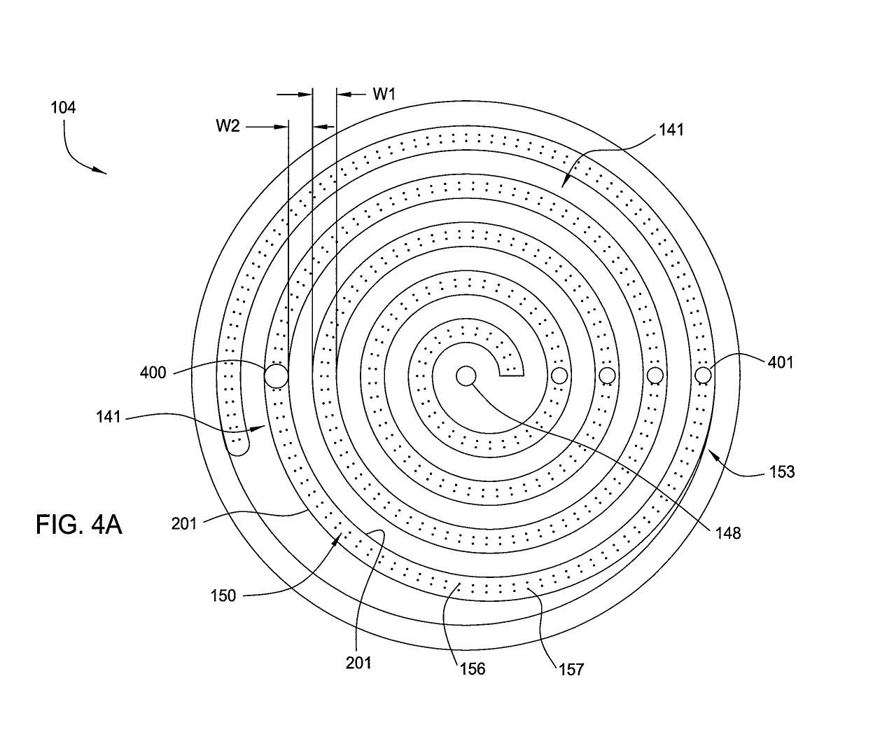

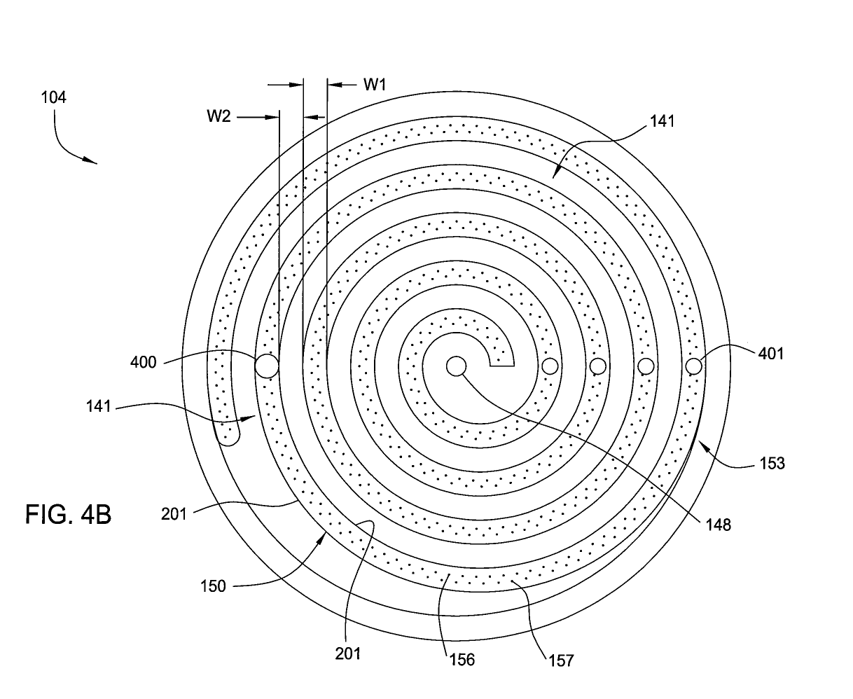

FIG. 4A is a schematic bottom view of the showerhead assembly shown in FIG. 1B according to one embodiment of the present invention. The spiral channel geometry of showerhead assembly 104 is reflected by the spiral arrangement of the first and second gas injection holes 156 and 157 which are disposed at the bottom of first and second gas channels 142, 143 which form a repeating radial gas channel sequence 142-143-repeat across showerhead face 153. A spiral mixing channel 150 is recessed from showerhead face 153 and has vertical walls 201. Heat exchanging channel 141 is a spiral channel having width W2 disposed adjacent to the mixing channel 150 having width W1.

A central conduit 148 may be located at or near the center of the showerhead assembly 104, and several embodiments for the central conduit 148 have been previously described herein. In another embodiment, central conduit 148 may be replaced with a heat exchanging fluid conduit 232. One or more ports 400 and 401 may be disposed about the central conduit 148, and the port 400 and 401 diameters may be the same or different depending upon the intended function of each port 400 and 401. In one embodiment, the ports 400 and/or 401 may be used to house temperature sensors such as pyrometers or thermocouples to measure substrate temperature and/or other temperatures, such as the temperature of the showerhead face 153. Ports 400, 401 may be connected to and in fluid communication with sensor tubes 301. In another embodiment, the ports 400 and 401 may be disposed on the showerhead assembly 104 to avoid intersecting with the heat exchanging channel 141.

In another embodiment, the ports 400 and/or 401. may be used as metrology ports and may be coupled to one or more metrology tools (not shown). The metrology tool may be used to measure various film properties, such as real time film growth, thickness, roughness, composition, or other properties. One or more ports 400 and 401 may also be angled to enable use of a metrology tool, such as for reflectance measurements which may require an angled emitter and receiver for a reflected laser beam, for example.

Each port 400 and 401 may also be adapted to flow a purge gas (which may be an inert gas, such as nitrogen or argon) to prevent condensation on devices within ports 400 and 401 and enable accurate in situ measurements. The purge gas may have annular flow around a sensor, probe, or other device which is disposed inside sensor tube 301 and adjacent to port 400, 401. In another embodiment, the ports 400, 401 may have a diverging nozzle design so that the purge gas flow path widens as the gas moves downstream towards substrates 140. The diverging nozzle may be a countersink, chamfer, radius or other feature which widens the gas flow path. In one embodiment, the purge gas may have a flow rate of about 50 sccm (standard cubic centimeters per minute) to about 500 sccm.

FIG. 4B is a schematic bottom view of the showerhead assembly shown in FIG. 1B according to another embodiment of the present invention. The first gas injection holes 156 are staggered relative to the second gas injection holes 157 along the spiral mixing channel 150. The staggering of the first and second gas injection holes 156 and 157 may facilitate more uniform gas distribution over the surfaces of substrates 140.

FIG. 5 is a schematic bottom view of additional embodiments of a showerhead assembly according to the present invention. A plurality of gas injection holes 502 are in fluid communication with spiral gas channels such as first and second gas channels 142, 143. Heat exchanging channel 141 may be disposed adjacent to the gas channels.

In one embodiment, as shown in quadrant IV, the same-sized gas injection holes 502 may be used across showerhead face 153. Each gas channel may supply a different gas, such as an MO precursor, nitrogen precursor, or inert gas, for example, to the gas injection holes 502 which are in fluid communication with the gas channel. The gas channel dimensions (such as length and width) and number and locations of gas conduits 147 for second gas channel 143 may be selected to help achieve proportional gas flow so that approximately the same amount of gas over time is delivered to each gas channel which delivers the same precursor (or inert gas). The diameters of the gas injection holes 502 may be suitably sized to help ensure that the gas flow rate is about the same through each gas injection hole 502 along each gas channel which flows the same precursor. Mass flow controllers (not shown) may be disposed upstream of the showerhead assembly 104 so that the flow rate of each precursor to the gas channels may be adjusted and thereby control the precursor stochiometry of process gas 152. However, under certain conditions, it may also be desirable to increase or decrease the process gas 152 flow rate at various locations along the showerhead face 153.

In one embodiment, shown in quadrant I, larger gas injection holes 503 having diameters greater than the diameters of gas injection holes 502 may be used near the outer perimeter 504 of the showerhead assembly 104 to help compensate for gas flow anomalies which may exist near the annular exhaust channel 105 and outer edges of the substrate carrier 114. For example, the vacuum of the annular exhaust channel 105 may deplete the process gas 152 near outer perimeter 504 and larger gas injection holes 503 may help compensate for the gas depletion. In one embodiment, the ratio of the larger gas injection hole 503 diameter to the diameter of gas injection hole 502 ranges from about 1:1 to about 1.4:1.

Quadrant II shows another embodiment which uses a greater hole density (number of holes per unit area) for gas injection holes 502 near the outer perimeter 504 of the showerhead assembly 104 which may help provide more uniform gas distribution over substrates 140. A pitch P is the shortest distance between gas injection holes 502 along the same gas channel, and separation distance X is the shortest distance between gas injection holes 502 disposed in adjacent gas channels. The pitch P may be changed to increase or decrease the hole density over desired areas of the showerhead assembly 104. In the present embodiment, the pitch P is decreased to increase the hole density near outer perimeter 504 while separation distance X remains unchanged. In other embodiments, separation distance X and/or the dimensions of the gas channels may also be changed to increase or decrease the hole density. In one embodiment, the ratio of the pitch P near outer perimeter 504 to a normal pitch P away from outer perimeter 504 may range from about 1:1 to about 0.5:1.

In yet another embodiment, shown in quadrant III, larger gas injection holes 503 may be used for one or more precursors and/or inert gases to help achieve the desired gas flow, gas distribution and/or gas stochiometry across showerhead face 153. In other embodiments, the gas injection hole 502 diameters and hole densities may be varied as desired across showerhead assembly 104. The embodiments shown in FIG. 5 and described herein may be combined and used with other embodiments described herein for showerhead assembly 104.

In the embodiments previously discussed herein, a plurality of gas injection holes have been disposed along the lengths of spiral gas channels to inject gases along the length of a spiral mixing channel 150, as shown in FIGS. 2B, 2D, and 4A. A gas channel sequence may comprise two or more adjacent channels which may carry precursor gases and inert gases to form a radial gas injection sequence, such as MO—NH₃ for example, which repeats along a radius of the showerhead assembly 104. The gas injection holes for each gas channel form a spiral gas injection zone which injects the precursor gas or inert gas carried by the channel. The gas injection zones are spirals and the radial gas injection sequence may refer to the sequence of gases which may repeat along a radius of the showerhead face 153. In other embodiments, the gas injection zones may have other shapes.

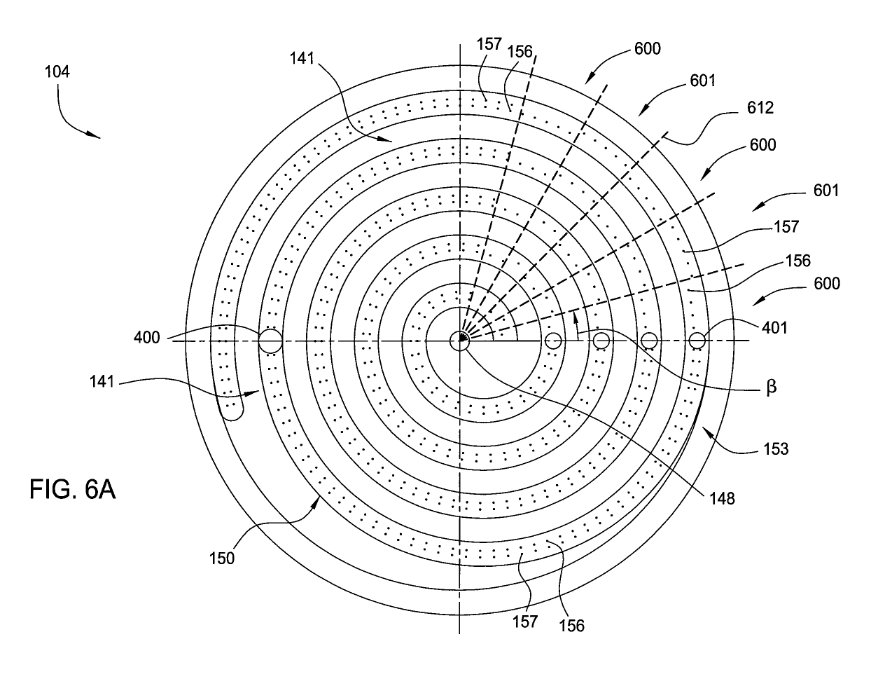

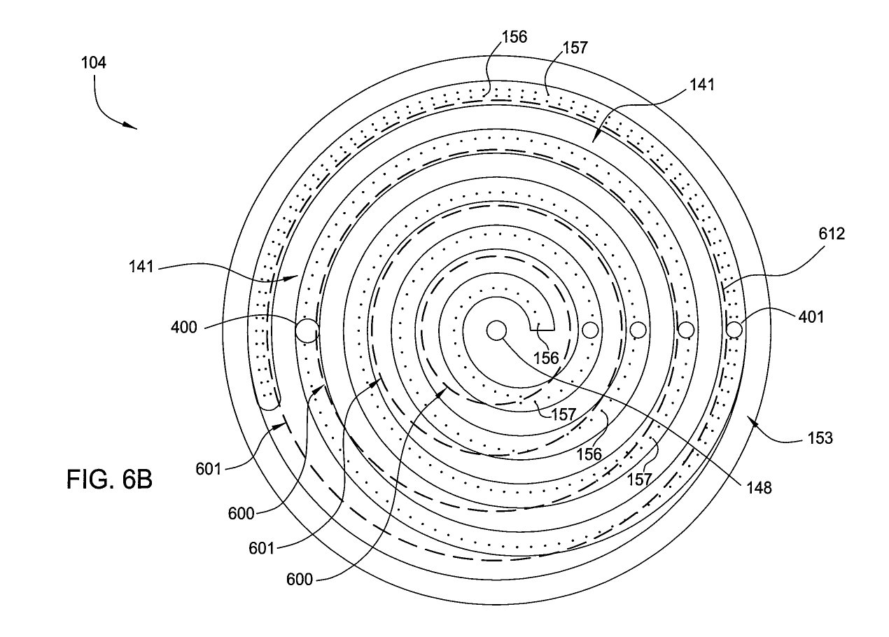

FIGS. 6A and 6B are schematic bottom views of a showerhead assembly which show different embodiments for gas injection zones. FIG. 6A depicts wedge shaped gas injection zones for a plurality of first and second gas injection holes 156, 157 which are in fluid communication with first and second gas channels 142, 143 for showerhead assembly 104. The radial gas channel sequence is 142-143-repeat. In other embodiments, a plurality of spiral gas channels may be used to form radial gas channel sequences which comprise more than two channels per sequence.

The first and second gas injection holes 156, 157 may be suitably located along each of the first and second gas channels 142, 143 to form gas injection zones 600 and 601 having boundaries indicated by dashed lines 612. By suitably locating the gas injection holes along the spiral gas channels, many gas injection zone shapes are possible. Further, the gas injection holes may be suitably spaced along the gas channels to optimize the gas flow distribution for each gas injection zone. In this example, the gas injection zones are wedge shaped and shown only for a portion of one quadrant of showerhead assembly 104.

Each gas injection zone 600 and 601 may supply a different gas to the processing chamber 102. For example, gas injection zone 600 comprises only first gas injection holes 156 which are in fluid communication with (e.g., using drilled holes) only first gas channel 142 and gas injection zone 601 comprises only second gas injection holes 157 which are in fluid communication with only second gas channel 143.

In one embodiment, first gas channel 142 may supply an MO precursor and second gas channel 143 may supply a nitrogen precursor such as ammonia (NH₃) to form an azimuthal (from one wedge shaped zone to the next in a clockwise or counterclockwise sense) gas injection sequence MO—NH3-repeat which corresponds to gas injection zones 600-601-repeat. In other embodiments, any number of gas injection sequences and zones may be formed by a suitable choice of gas injection hole locations, the number of different gas channels for showerhead assembly 104, and the number of different gases used. For example, the addition of a third gas channel 304 and third plenum 306 could provide a third wedge shaped gas injection zone which supplies a third precursor to form an azimuthal gas injection sequence MO—NH₃-(third precursor)-repeat. In other embodiments, one of the precursors may be replaced by an inert gas which may, for example, be used to separate the precursors. An angle β for each wedge shaped zone may be suitably chosen for the desired number of repeated gas injection sequences and desired zone sizes within 360 degrees for showerhead assembly 104. In the present embodiment, the gas injection zones 600 and 601 are wedge shaped, but the gas injection hole locations along each spiral channel may be adapted to form many other zone shapes.

FIG. 6B shows another embodiment for gas injection zones 600 and 601 shaped as concentric rings. The first and second gas injection holes 156, 157 are suitably located along each first and second gas channel 142, 143 to form concentric gas injection zones 600 and 601 having boundaries indicated by dashed lines 612. Gas injection zones 600 comprise only first gas injection holes 156 and gas injection zones 601 comprise only second gas injection holes 157. A radial gas injection sequence MO—NH3-repeat (from center zone to outer zone) which corresponds to concentric gas injection zones 600-601-repeat may be formed, but other gas injection sequences are possible. Additionally, the gas injection hole diameters and hole densities may be varied as desired within each gas injection zone. The embodiments shown in FIGS. 6A and 6B and described herein may be combined and used with other embodiments described herein for showerhead assembly 104.

The previous showerhead assembly 104 embodiments described herein for MOCVD applications may be adapted for use in another deposition technique known as hydride vapor phase epitaxy (HVPE). The HVPE process offers several advantages in the growth of some Group III-V films, GaN in particular, such as high growth rate, relative simplicity, and cost effectiveness. In this technique, the growth of GaN proceeds due to the high temperature, vapor phase reaction between gallium chloride (GaCl) and ammonia (NH₃). The ammonia may be supplied from a standard gas source, while the GaCl is produced by passing a hydride-containing gas, such as HCl, over a heated liquid gallium supply. The two gases, ammonia and GaCl, are directed towards a heated substrate where they react to form an epitaxial GaN film on the surface of the substrate. In general, the HVPE process may be used to grow other Group III-nitride films by flowing a hydride-containing gas (such as HCl, HBr, or HI) over a Group III liquid source to form a Group III-halide gas, and then mixing the Group III-halide gas with a nitrogen-containing gas such as ammonia to form a Group III-nitride film.

In one embodiment, the gas delivery system 125 may comprise a heated source boat (not shown) external to chamber 102. The heated source boat may contain a metal source (e.g., Ga) which is heated to the liquid phase, and a hydride-containing gas (e.g., HCl) may flow over the metal source to form a Group III-halide gas, such as GaCl. The Group III-halide gas and a nitrogen-containing gas, such as NH₃, may then be delivered to first and second plenums 144, 145 of showerhead assembly 104 via supply lines 131, 132 for injection into the processing volume 108 to deposit a Group III-nitride film, such as GaN, on substrates 140. In another embodiment, one or more supply lines 131, 132 may be heated to deliver the precursors from an external boat to chamber 102. In another embodiment, an inert gas, which may be hydrogen, nitrogen, helium, argon or combinations thereof, may be flowed between first and second HVPE precursor gases to help keep the precursors separated before reaching the substrates 140. The HVPE precursor gases may also include dopant gases.

In addition to the Group III precursors previously mentioned herein, other Group III precursors may be used with showerhead assembly 104. For example, precursors having the general formula MX₃ where M is a Group III element (e.g., gallium, aluminum, or indium) and X is a Group VII element (e.g., bromine, chlorine or iodine) may also be used (e.g., GaCl₃). Components of the gas delivery system 125 (e.g., bubblers, supply lines) may be suitably adapted to deliver the MX₃ precursors to showerhead assembly 104.

While the foregoing is directed to embodiments of the present invention, and further embodiments of the invention may be devised without departing the basic scope thereof, and the scope thereof is determined by the claims follow.

1. A showerhead apparatus comprising:
a first gas channel for a first precursor gas; and
a second gas channel for a second precursor gas, arranged to be coplanar with the first gas channel.

2. The apparatus of claim 1, wherein the first and second gas channels are arranged in an interleaved manner.

3. The apparatus of claim 2, wherein the first and second gas channels comprise spiral channels.

4. The apparatus of claim 2, further comprising a first plenum for supplying the first precursor gas to the first gas channel and a second plenum for supplying the second precursor gas to the second gas channel, wherein the first and second plenums are arranged above the first and second gas channels.

5. The apparatus of claim 4, wherein the first and second plenums are arranged one above the other.

6. The apparatus of claim 3, further comprising a third spiral channel for a heat exchanging medium.

7. The apparatus of claim 6, further comprising a fourth spiral channel for a gas, arranged to be coplanar with the first and second spiral gas channels.

8. The apparatus of claim 3, wherein the first and second spiral gas channels have injection holes that are arranged to define a plurality of injection zones.

9. The apparatus of claim 8, wherein the injection zones are concentric and alternate between an injection zone for a first precursor gas and an injection zone for a second precursor gas.

10. The apparatus of claim 8, wherein the injection zones are wedge-shaped and alternate between an injection zone for a first precursor gas and an injection zone for a second precursor gas.

11. The apparatus of claim 8, further comprising a third spiral gas channel having injection holes that are arranged to define inert gas injection zones between the plurality of injection zones for the first and second precursor gases.

12. A showerhead apparatus comprising:
a first gas channel for a first precursor gas having injection holes through which the first precursor gas is injected into a precursor mixing zone; and
a second gas channel for a second precursor gas having injection holes through which the second precursor gas is injected into the precursor mixing zone.

13. The apparatus of claim 12, wherein the first and second gas channels comprise spiral channels arranged in an interleaved manner.

14. The apparatus of claim 12, wherein the size of the injection holes through which the first and second precursor gases are injected have the same hole diameters.

15. The apparatus of claim 14, wherein the density of the injection holes through which the first and second precursor gases are injected are different, such that the hole density is greater at regions closer to the outer periphery of the showerhead apparatus.

16. The apparatus of claim 12, wherein the size of the injection holes through which the first and second precursor gases are injected have different hole diameters, such that the hole diameters are larger at hole positions closer to the outer periphery of the showerhead apparatus.

17. The apparatus of claim 12, wherein the size of the injection holes through which the first precursor gas is injected is different from the size of the injection holes through which the second precursor gas is injected.

18. The apparatus of claim 12, wherein the precursor mixing zone is defined on a side of the showerhead apparatus that faces a substrate processing volume.

19. The apparatus of claim 18, wherein the gas injection holes are staggered along the mixing zone.

20. The apparatus of claim 18, further comprising heat exchanging channels formed on the side of the showerhead apparatus that faces the substrate processing volume.

21. The apparatus of claim 20, wherein the heat exchanging channels have a plurality of walls that extend toward the substrate processing volume and define the mixing zone.

22. A showerhead apparatus comprising:
a first channel for a first precursor gas;
a second channel for a second precursor gas; and
a third channel for a heat exchanging medium.

23. The apparatus of claim 22, wherein the first and second channels are coplanar and interleaved.

24. The apparatus of claim 23, wherein the first and second channels comprise spiral channels.

25. The apparatus of claim 23, wherein the first and second channels have injection holes through which the first and second precursor gases are injected into a mixing zone that is defined by walls of the third channel.

26. The apparatus of claim 24, further comprising a fourth spiral channel for an inert gas.

27. The apparatus of claim 22, wherein the first precursor gas comprises a Group III precursor gas and the second precursor gas comprises a Group V precursor gas.

28. The apparatus of claim 27, wherein the first and second precursor gases comprise HVPE precursor gases.

29. The apparatus of claim 27, wherein the first and second precursor gases comprise MOCVD precursor gases.

30. The apparatus of claim 27, wherein the first and second precursor gases comprise precursor gases having the general formula MX₃ and M includes one of gallium, aluminum or indium and X includes one of chlorine, bromine, or iodine.

31. The apparatus of claim 22, further comprising one or more temperature sensors for measuring the temperature of the showerhead, wherein the flow rate and temperature of heat exchanging fluid that flows through the heat exchanging channels is controlled based on the measured temperature.

32. The apparatus of claim 27, wherein the first and second precursor gases comprise plasma species.
